(19) United States
(12) Patent Application Publication
(10) Pub. No.: US 2012/0201079 A1
(43) Pub. Date: Aug. 9, 2012

(54) SEMICONDUCTOR MEMORY DEVICE IN WHICH CAPACITANCE BETWEEN BIT LINES IS REDUCED, AND METHOD OF MANUFACTURING THE SAME

(76) Inventor: Noboru Shibata, Kawasaki-shi (JP)

(21) Appl. No.: 13/218,723

(22) Filed: Aug. 26, 2011

(30) Foreign Application Priority Data
Feb. 4, 2011 (JP) 2011-023214

(51) Int. Cl. G11C 16/04; H01L 21/762

(52) U.S. Cl. 365/185.05; 438/430; 257/E21.546

(57) ABSTRACT

According to one embodiment, a semiconductor memory device includes a plurality of memory cells arranged in a matrix, a plurality of word lines for selecting a plurality of memory cells, and a plurality of bit lines for selecting a plurality of memory cells. Of the plurality of bit lines, first bit lines and second bit lines are arranged in different layers.

### CROSS-REFERENCE TO RELATED APPLICATIONS

This application is based upon and claims the benefit of priority from prior Japanese Patent Application No. 2011-023214, filed Feb. 4, 2011, the entire contents of which are incorporated herein by reference.

### FIELD

Embodiments described herein relate generally to a semiconductor memory device, e.g., a NAND flash memory.

### BACKGROUND

In a NAND flash memory, all or half of a plurality of memory cells arranged in the row direction are connected to a plurality of bit lines. These bit lines are connected to a plurality of latch circuits for write and read to data of the memory cell. A write or read operation is performed at once for all or half of the memory cells arranged in the row direction.

Also, in a NAND flash memory, the number of cells connected to one bit line is increased as the capacity increases. In this case, the length of the bit line increases, the capacitance between the bit lines increases, and the CR time constant undesirably increases.

### BRIEF DESCRIPTION OF THE DRAWINGS

FIG. 1 is a block diagram schematically showing an example of a NAND flash memory applied to an embodiment;

FIG. 2 is a circuit diagram schematically showing the arrangement of a part of FIG. 1;

FIG. 3 is a circuit diagram schematically showing the arrangement of the part of FIG. 1, as an example different from that shown in FIG. 2;

FIGS. 4A and 4B are sectional views showing a memory cell and selection transistor;

FIG. 5 is a sectional view showing the NAND flash memory;

FIG. 6 is a view showing examples of voltages to be applied to individual regions shown in FIG. 5;

FIG. 7 is a circuit diagram showing an example of a data storage circuit shown in FIGS. 2 and 3;

FIGS. 8A, 8B, and 8C are views showing the relationship between data and a threshold voltage when storing two-bit data in a memory cell;

FIG. 9 is a flowchart showing the programming operation of the first page;

FIG. 10 is a flowchart showing the programming operation of the second page;

FIG. 11A is an exploded view of a semiconductor memory device according to the first embodiment, and

FIG. 11B is a sectional view of FIG. 11A;

FIG. 12 is a plan view showing the floor plan of the semiconductor memory device according to the first embodiment;

FIG. 13 is a plan view showing the floor plan of a general semiconductor memory device;

FIG. 14 is a sectional view schematically showing the relationship between bit lines BLO and BLE and contacts shown in FIGS. 11A and 11B;

FIG. 15 is a sectional view schematically showing the first modification of FIG. 14;

FIG. 16 is a sectional view schematically showing the second modification of FIG. 14;

FIG. 17A is an exploded view of a semiconductor memory device according to the second embodiment, and

FIG. 17B is a sectional view of FIG. 17A;

FIG. 18 is a sectional view schematically showing the relationship between bit lines BLO and BLE and contacts in the second embodiment;

FIG. 19 is a sectional view schematically showing the first modification of FIGS. 17A and 17B;

FIG. 20 is a sectional view schematically showing the second modification of FIGS. 17A and 17B;

FIGS. 21A, 21B, 21C, 21D, 21E, 21F, 21G, 21H, 21I, and 21J are sectional views schematically showing a method of manufacturing the semiconductor memory devices according to the first and second embodiments;

FIG. 22 is a sectional view schematically showing a modification of FIGS. 14, 15, and 16;

FIG. 23 is a sectional view schematically showing a modification of FIGS. 14, 15, and 16;

FIG. 24 is a sectional view schematically showing a modification of FIGS. 18, 19, and 20;

FIG. 25 is a sectional view schematically showing a modification of FIGS. 18, 19, and 20;

FIG. 26 is a sectional view schematically showing a modification of FIGS. 24 and 25;

FIG. 27 is a sectional view schematically showing a modification of FIGS. 24 and 25;

FIG. 28 is a sectional view schematically showing a modification of FIGS. 24 and 25; and

FIG. 29 is a circuit diagram showing a modification of FIG. 3.

### DETAILED DESCRIPTION

In general, according to one embodiment, a semiconductor memory device includes a plurality of memory cells arranged in a matrix, a plurality of word lines for selecting a plurality of memory cells, and a plurality of bit lines for selecting a plurality of memory cells. Of the plurality of bit lines, first bit lines and second bit lines are arranged in different layers.

An embodiment will be explained below with reference to the accompanying drawing.

In this embodiment, adjacent bit lines are formed in different interconnection layers in order to reduce the capacitance between the bit lines.

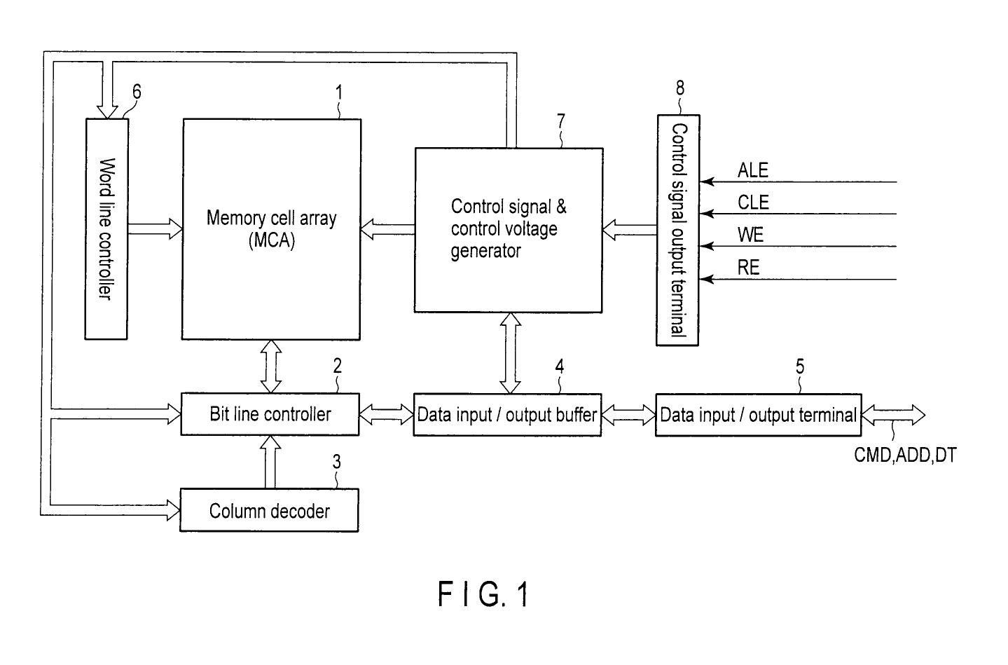

FIG. 1 shows an outline of the arrangement of a NAND flash memory for storing, e.g., two-bit quaternary data according to this embodiment.

A memory cell array 1 includes a plurality of bit lines, a plurality of word lines, a common source line, and electrically programmable memory cells such as EEPROM cells arranged in a matrix. The memory cell array 1 is connected to a bit line controller 2 for controlling the bit lines and a word line controller 6.

The bit line controller 2 reads out data from a memory cell in the memory cell array 1 via a bit line, detects the state of a memory cell in the memory cell array 1 via a bit line, and writes data in a memory cell in the memory cell array by applying a write control voltage to the memory cell via a bit line. The bit line controller 2 is connected to a column decoder 3 and data input/output buffer 4. The column decoder 3 selects an internal data storage circuit of the bit line controller 2. Memory cell data read out to the data storage circuit is output outside from a data input/output terminal 5 via the data input/output buffer 4. Various commands CMD for controlling the operation of the NAND flash memory, an address ADD, and data DT, all of which are externally supplied, are input to the data input/output terminal 5. Write data input to the data input/output terminal 5 is supplied to a data storage circuit selected by the column decoder 3 via the data input/output buffer 4, and commands and addresses are supplied to a control signal & control voltage generator 7.

The word line controller 6 is connected to the memory cell array 1. The word line controller 6 selects a word line in the memory cell array 1, and applies a voltage necessary for read, write, or erase to the selected word line.

The memory cell array 1, bit line controller 2, column decoder 3, data input/output buffer 4, and word line controller 6 are connected to the control signal & control voltage generator 7, and controlled by the control signal & control voltage generator 7. The control signal & control voltage generator 7 is connected a control signal input terminal 8, and controlled by control signals address latch enable (ALE), command latch enable (CLE), write enable (WE), and read enable (RW) externally input via the control signal input terminal 8.

The bit line controller 2, column decoder 3, word line controller 6, and control signal & control voltage generator 7 form a write circuit and read circuit.

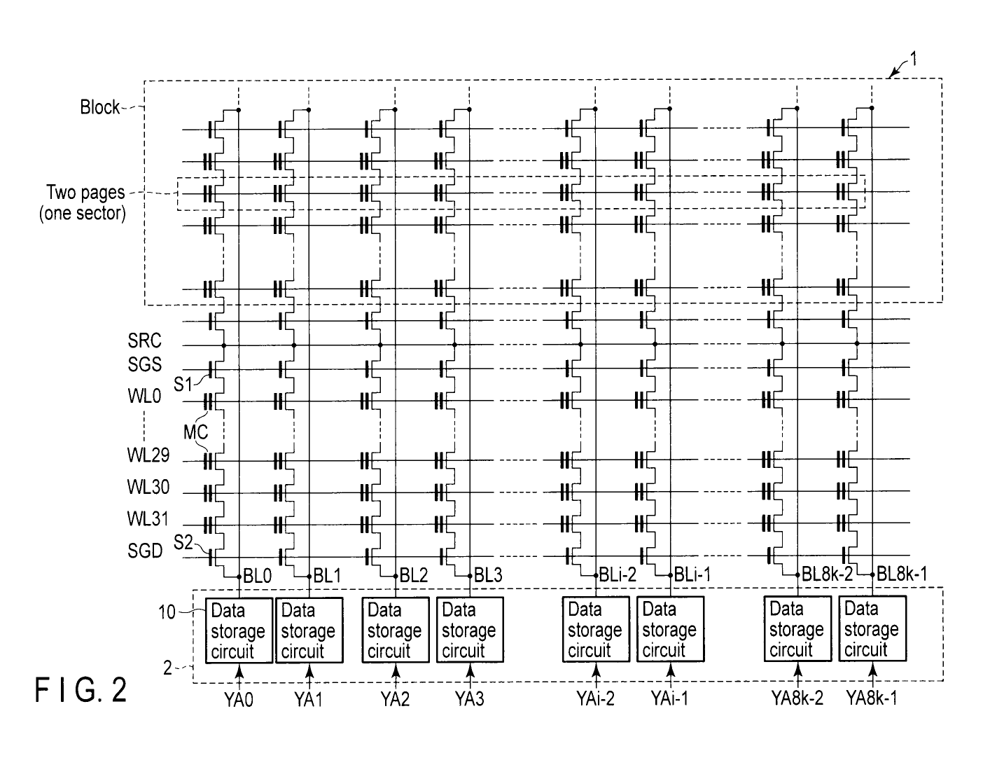

FIG. 2 shows an example of the configuration of the memory cell array 1 and bit line controller 2 shown in FIG. 1. A plurality of NAND cells are arranged in the memory cell array 1. Each NAND cell includes, e.g., 32 series-connected EEPROM memory cells MC, and select gates S1 and S2. The select gate S2 is connected to a bit line BL0e, and the select gate S1 is connected to a source line SRC. The control gates of the memory cells MC arranged in each row are connected together to a corresponding one of word lines WL0 to WL29, WL30, and WL31. Also, the select gates S2 are connected together to a select line SGD, and the select gates S1 are connected together to a select line SGS.

The bit line controller 2 includes a plurality of data storage circuits 10. Bit lines BL0, BL1, . . . , BLi−1, BLi, . . . , BLk−2, and BLk−1 are connected to corresponding data storage circuits 10.

The memory cell array 1 includes a plurality of blocks as indicated by the broken lines. Each block includes a plurality of NAND cells, and data is erased for, e.g., each block. Also, an erase operation is performed for bit lines connected to the data storage circuits 10 at once.

Furthermore, a plurality of memory cells connected to each word line (i.e., memory cells within the range enclosed by the broken lines) form a sector. Data is written in and read out from each sector. That is, the write or read operation is executed for all memory cells arranged in the row direction.

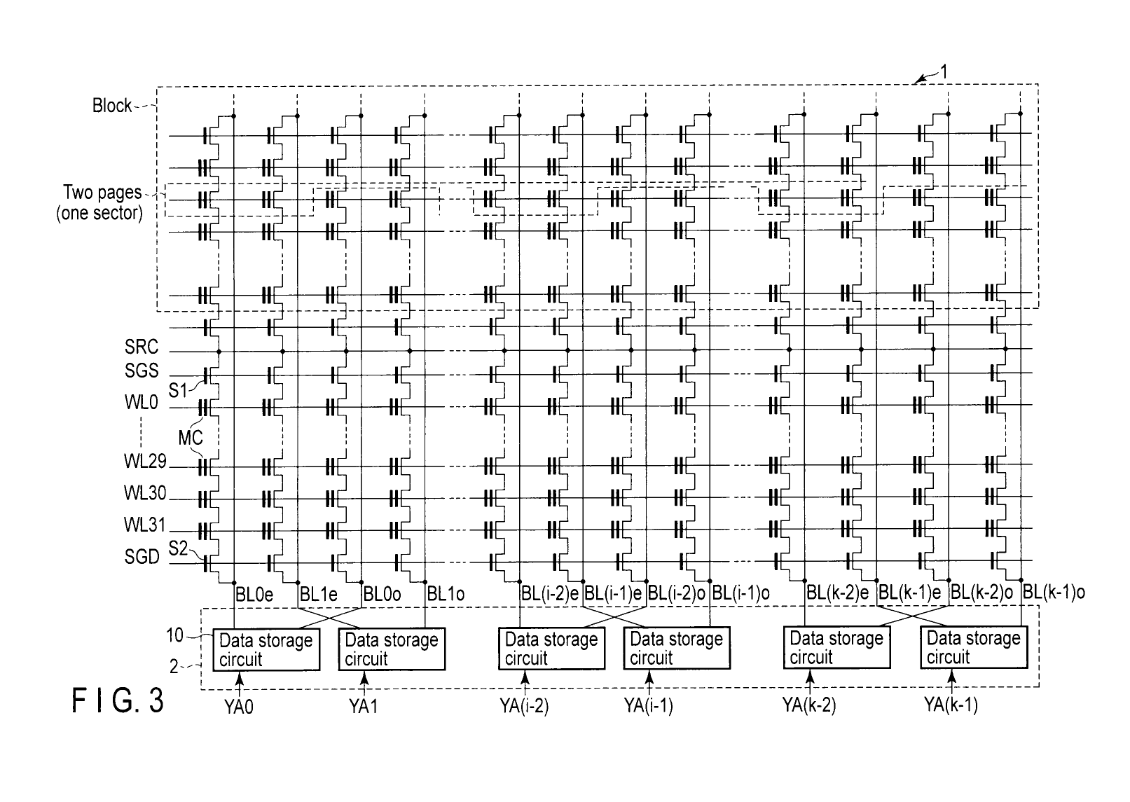

FIG. 3 shows an arrangement in which half of a plurality of memory cells arranged in the row direction are connected to one data storage circuit 10 via a bit line in read and programming. When half bit lines are connected to one data storage circuit, BL(i−2)e, BL(i−2)o, BLie, BLio, . . . , (even-numbered bit lines) and BL(i−3)e, BL(i−3)o, BL(i−1)e, BL(i−1)o, . . . , (odd-numbered bit lines) are arranged in different layers, the even-numbered bit lines are arranged in the same layer, and the odd-numbered bit lines are arranged in the same layer. Therefore, the bit lines BL(i−2)e and BL(i−2)o arranged in the same layer are connected to one data storage circuit 10, and the bit lines BL(i−1)e and BL(i−1)o arranged in the same layer are connected to one data storage circuit 10.

BL0e, BL1e, BL2e, BL3e, . . . , BL(i−2)e, BL(i−1)e, . . . are selected as one page, and BL0o, BL1o, BL2o, BL3o, . . . , BL(i−2)o, BL(i−1)o, . . . are selected as another page. In this configuration, adjacent bit lines in the same layer are shielded.

In a read operation, program verify operation, and programming operation, one of two bit lines (BL0e and BL0o, . . . , BL(i−2)e and BL(i−2)o, BL(i−1)e and BL(i−1)o, . . . , BL(k−1)e and BL(k−1)o) connected to each data storage circuit 10 is selected in accordance with an externally supplied address signal. In addition, one word line is selected in accordance with the external address, and two pages (one sector) indicated by the broken lines are selected. These two pages are switched by the address.

As another example of the arrangement in which half bit lines are connected to one data storage circuit, BL(i−2)e, BL(i−1)e, BLie, . . . shown in FIG. 3 are arranged in the first layer, and BL(i−2)o, BL(i−1)o, BLio, . . . shown in FIG. 3 are arranged in the second layer different from the first layer. When the bit lines in the first layer are selected, the bit lines in the second layer are unselected; when the bit lines in the second layer are selected, the bit lines in the first layer are unselected. Although adjacent bit lines on the same layer are selected or unselected together, bit lines in vertically adjacent layers can be shielded from each other.

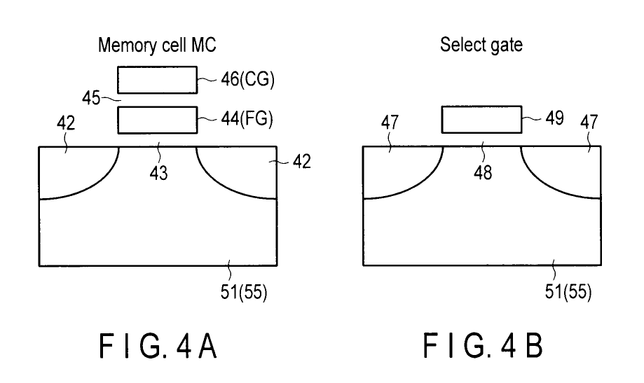

FIGS. 4A and 4B are sectional views of the memory cell and selection transistor. FIG. 4A shows the memory cell. N-type diffusion layers 42 as the source and drain of the memory cell are formed in a substrate 51 (a p-type well region 55 to be described later). A floating gate (FG) 44 is formed on an insulating film 43 on the p-type well region 55. A control gate (CG) 46 is formed on an insulating film 45 on the floating gate 44. FIG. 4B shows the select gate. N-type diffusion layers 47 as the source and drain are formed in the p-type well region 55. A control gate 49 is formed on a gate insulating film 48 on the p-type well region 55.

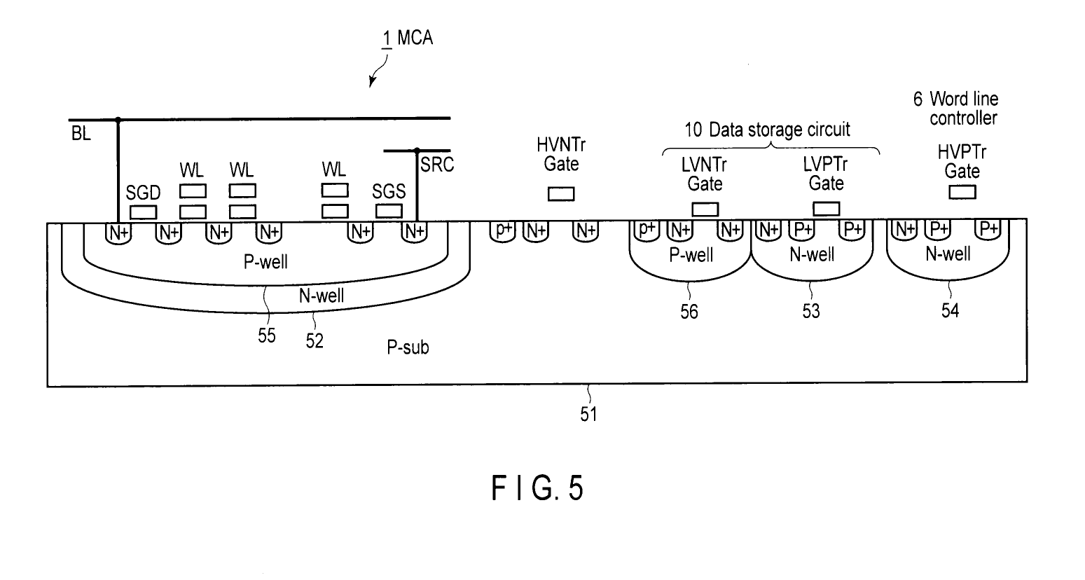

FIG. 5 is a sectional view of the NAND flash memory. N-type well regions 52, 53, and 54 and a p-type well region 56 are formed in, e.g., the p-type semiconductor substrate 51. The p-type well region 55 is formed in the n-type well region 52. Memory cells Tr forming the memory cell array 1 are formed in the p-type well region 55. In addition, a low-voltage p-channel transistor LVPTr and low-voltage n-channel transistor LVNTr forming the data storage circuit 10 are respectively formed in the n-type well region 53 and p-type well region 56. A high-voltage n-channel transistor HVNTr for connecting a bit line and the data storage circuit 10 is formed in the substrate 51. Also, a high-voltage p-channel transistor HVPTr forming, e.g., a word line driver is formed in the n-type well region 54. As shown in FIG. 5, the high-voltage transistors HVNTr and HVPTr have gate insulating films thicker than those of the low-voltage transistors LVNTr and LVPTr.

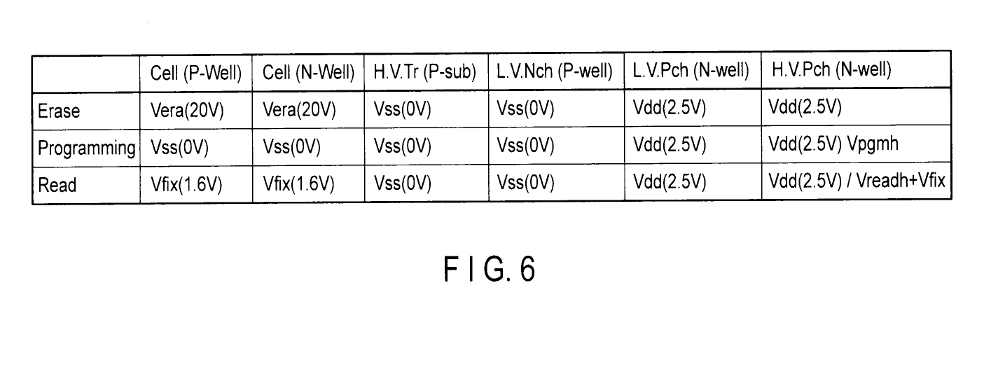

FIG. 6 shows examples of voltages to be applied to the individual regions shown in FIG. 5. In erase, programming, and read, the voltages as shown in FIG. 6 are applied to the individual regions. Vera is a voltage to be applied to the substrate when erasing data. Vss is a ground voltage. Vdd is a power supply voltage. Vpgmh is a voltage Vpgm+Vth to be applied to a word line when writing data. Vreadh is a voltage Vread+Vth to be applied to a word line when reading out data.

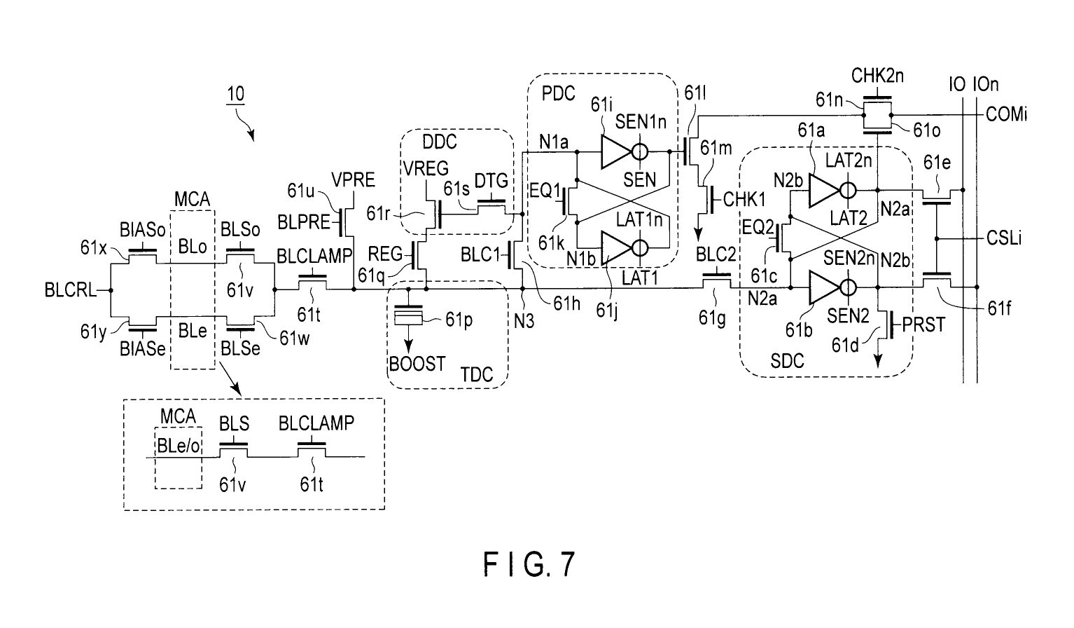

FIG. 7 is a circuit diagram showing an example of the data storage circuit 10 shown in FIG. 3.

The data storage circuit 10 includes a primary data cache (PDC), secondary data cache (SDC), dynamic data cache (DDC), and temporary data cache (TDC). The SDC, PDC, and DDC hold input data in a write operation, hold readout data in a read operation, temporarily hold data in a verify operation, and are used to manipulate internal data when storing multilevel data. The TDC amplifies and temporarily holds bit line data in data read, and is used to manipulate internal data when storing multilevel data.

The SDC includes clocked inverter circuits 61a and 61b forming a latch circuit, and transistors 61c and 61d. The transistor 61c is connected between the input terminal of the clocked inverter circuit 61a and the input terminal of the clocked inverter circuit 61b. A signal EQ2 is supplied to the gate of the transistor 61c. The transistor 61d is connected between the output terminal of the clocked inverter circuit 61b and ground. A signal PRST is supplied to the gate of the transistor 61d. A node N2a of the SDC is connected to an input/output data line 10 via a column selection transistor 61e. A node N2b of the SDC is connected to an input/output data line IOn via a column selection transistor 61f. A column selection signal CSLi is supplied to the gates of the transistors 61e and 61f. The node N2a of the SDC is connected to a node N1a of the PDC via transistors 61g and 61h. A signal BLC2 is supplied to the gate of the transistor 61g. A signal BLC1 is supplied to the gate of the transistor 61h.

The PDC includes clocked inverter circuits 61i and 61j and a transistor 61k. The transistor 61k is connected between the input terminal of the clocked inverter circuit 61i and the input terminal of the clocked inverter circuit 61j. A signal EQ1 is supplied to the gate of the transistor 61k. A node N1b of the PDC is connected to the gate of a transistor 61l. One end of the current path of the transistor 61l is grounded via a transistor 61m. A signal CHK1 is supplied to the gate of the transistor 61m. The other end of the current path of the transistor 61l is connected to one end of the current path of transistors 61n and 61o forming a transfer gate. A signal CHK2n is supplied to the gate of the transistor 61n. The gate of the transistor 61o is connected to the output terminal of the clocked inverter circuit 61a. A line COMi is connected to the other end of the current path of the transistors 61n and 61o. The line COMi is a common line for all the data storage circuits 10. The potential of the line COMi changes to High level when verify of all the data storage circuits 10 is complete. That is, the node N1b of the PDC changes to Low level when verify is complete, as will be described later. When the signals CHK1 and CHK2n are changed to High level in this state, the potential of the line COMi changes to High level if verify is complete.

The TDC includes a MOS capacitor 61p. The capacitor 61p is connected between a connection node N3 of the transistors 61g and 61h and ground. The DDC is connected to the connection node N3 via a transistor 61q. A signal REG is supplied to the gate of the transistor 61q.

The DDC includes transistors 61r and 61s. A signal VREG is supplied to one end of the current path of the transistor 61r, and the other end of the current path is connected to the current path of the transistor 61q. The gate of the transistor 61r is connected to the node N1a of the PDC via the transistor 61s. A signal DTG is supplied to the gate of the transistor 61s.

Furthermore, one end of the current path of transistors 61t and 61u is connected to the connection node N3. A signal VPRE is supplied to the other end of the current path of the transistor 61u, and a signal BLPRE is supplied to the gate of the transistor 61u. A signal BLCLAMP is supplied to the gate of the transistor 61t. The other end of the current path of the transistor 61t is connected to one end of the bit line BLo via a transistor 61v, and connected to one end of the bit line BLe via a transistor 61w. The other end of the bit line BLo is connected to one end of the current path of a transistor 61x. A signal BIASo is supplied to the gate of the transistor 61x. The other end of the bit line BLe is connected to one end of the current path of a transistor 61y. A signal BIASe is supplied to the gate of the transistor 61y. A signal BLCRL is supplied to the other end of the current path of the transistors 61x and 61y. The transistors 61x and 61y are complementarily turned on with respect to the transistors 61v and 61w in accordance with the signals BIASo and BIASe, thereby supplying the potential of the signal BLCRL to an unselected bit line.

The control signal & control voltage generator 7 shown in FIG. 1 generates the above-mentioned signals and voltages, and controls the following operation.

The data storage circuit 10 shown in FIG. 2 has the same configuration as that shown in FIG. 7, except for the connection to a bit line. That is, as shown in FIG. 7, only the transistor 61v, for example, is connected to the other terminal of the transistor 61t, and the bit line BLe or BLo is connected via the transistor 61v.

This memory is a multilevel memory and can store two-bit data in one cell. Two bits are switched by addresses (first page and second page). When storing two bits in one cell, two pages are necessary. When storing three bits in one cell, the three bits are switched by addresses (first page, second page, and third page). When storing four bits in one cell, the four bits are switched by addresses (first page, second page, third page, and fourth page).

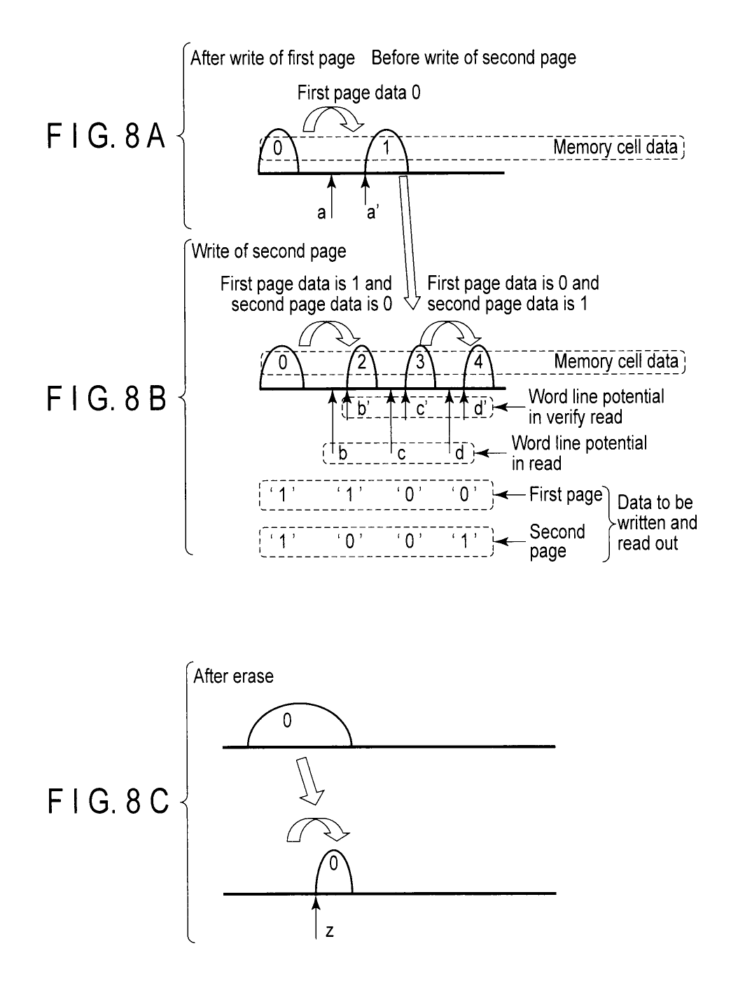

FIGS. 8A, 8B, and 8C illustrate the relationship between data and a threshold voltage when storing two-bit data in a memory cell. When performing an erase operation, the memory cell data becomes “0” as shown in FIG. 8C. After erase, write is performed using, e.g., verify level “z” in order to narrow the spread of the threshold distribution. This data “0” is set in, e.g., a negative threshold voltage distribution.

As shown in FIG. 8A, when write data is “1” in write of the first page, the memory cell data remains “0”. When the write data is “0”, the memory cell data becomes “1”.

As shown in FIG. 8B, after write of the second page, the memory cell data becomes one of “0”, “2”, “3”, and “4” in accordance with the write data. That is, when the memory cell data after write of the first page is “0” and the write data of the second page is “1”, the memory cell data remains “0”. When the write data is “0”, the memory cell data becomes “2”. Also, when the memory cell data after write of the first page is “1” and the write data is “0”, the memory cell data becomes “3”. When the write data is “1”, the memory cell data becomes “4”. In this embodiment, the memory cell data is defined from a low threshold voltage to a high threshold voltage. Also, data “1”, “2”, “3”, and “4” are, e.g., positive threshold voltages.

### (Read Operation)

As shown in FIG. 8A, after write of the first page, the memory cell data is data “0” or “1”. Accordingly, a read operation need only be performed at level “a”. Also, as shown in FIG. 8B, after write of the second page, the memory cell data is “0”, “2”, “3”, or “4”. Therefore, a read operation need only be performed at level “b”, “c”, or “d”. In this embodiment, assume that data “0” and data “2” are set on the negative side.

A read operation at each level will now be explained. First, the control signal & control voltage generator 7 applies a voltage Vfix (e.g., 1.6 V) to the well of a selected memory cell, the source line, an unselected bit line, and the select gate of an unselected block. Note that Vfix is 0 V if the threshold distribution is not set on the negative side.

A read potential Vfix+“a”, “b”, “c”, or “d” (Vfix+“a” is 1.1 V when, e.g., “a”=−0.5 V) is applied to a selected word line. Simultaneously, Vread+Vfix is applied to an unselected word line of a selected block, Vsg (Vdd+Vth)+Vfix (Vth is the threshold voltage of an n-channel MOS transistor) is applied to the select line SGD of the select gate S2 of the selected block, and Vfix is applied to the select line SGS of the select gate S1. Vfix is applied to the source line (SRC), and to the well in which a cell is formed.

Then, the signals VPRE, BLPRE, and BLCLAMP of the data storage circuit 10 shown in FIG. 7 are respectively once set at Vdd (e.g., 2.5 V), Vsg (Vdd+Vth), and, e.g., (0.6 V+Vth)+Vfix, and the bit line is precharged to, e.g., 0.6 V+Vfix=2.2 V.

Subsequently, Vsg (Vdd+Vth)+Vfix is applied to the select line SGS on the source side of the memory cell. Since the well and source are at Vfix, the memory cell is turned off if the threshold voltage of the memory cell is higher than level “a”, “b”, “c”, or “d” (e.g., “a”=−0.5 V). Accordingly, the bit line remains at High level (e.g., 2.2 V). Also, the memory cell is turned on if the threshold voltage of the memory cell is lower than level “a”, “b”, “c”, or “d”. Consequently, the bit line is discharged to the same potential as that of the source, i.e., Vfix (e.g., 1.6 V).

After that, the signal BLPRE of the data storage circuit 10 shown in FIG. 7 is once set at Vsg (Vdd+Vth), the node of the TDC is precharged to Vdd, and a signal BOOST is changed from Low level to High level, thereby setting TDC=αVdd (e.g., α=1.7, and αVdd=4.25 V). In this state, the signal BLCLAMP is set at, e.g., (0.45 V+Vth)+Vfix. The node N3 of the TDC changes to Low level (Vfix (e.g., 1.6 V)) when the bit line potential is lower than 0.45 V+Vfix, and remains at High level (αVdd (e.g., 4.25 V)) when the bit line potential is higher than 0.45 V.

After signal BLCLAMP=Vtr (e.g., 0.1V+Vth) is set, the signal BOOST is changed from High level to Low level. At Low level, the TDC decreases from Vfix (e.g., 1.6 V). Since signal BLCLAMP=Vtr (e.g., 0.1 V+Vth), however, the potential of the node N3 does not become lower than 0.1 V. Also, when the TDC is at Low level, the potential of the node N3 changes from αVDD (e.g., 4.25 V) to Vdd.

In this state, the signal BLC1 is set at Vsg (Vdd+Vth), and the potential of the TDC is read out to the PDC. Accordingly, the PDC changes to Low level when the threshold voltage of the memory cell is lower than level “a”, “b”, “c”, or “d”, and changes to High level when the threshold voltage is higher than level “a”, “b”, “c”, or “d”. Thus, a negative threshold value can be read out without setting a word line at a negative voltage.

### (Programming)

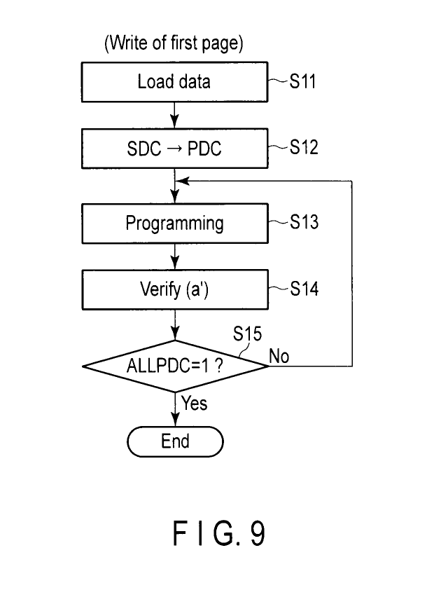

FIG. 9 is a flowchart of a programming operation.

In the programming operation, addresses are first designated to select, e.g., two pages shown in FIG. 2. This embodiment will be explained by taking, as an example, a programming operation performed in the order of the first page and second page of these two pages. First, the first page is selected by the address.

Then, write data is externally input and stored in the SDCs of all the data storage circuits 10 (S11). When a write command is input in this state, the data of the SDCs in all the data storage circuits 10 are transferred to the PDCs (S12). The node N1a of the PDC changes to High level if data “1” (no write is performed) is externally input, and changes to Low level if data “0” (write is performed) is externally input. After that, the data of the PDC is set at the potential of the node N1a of the data storage circuit 10, and the data of the SDC is set at the potential of the node N2a of the data storage circuit 10.

### (Programming Operation) (S13)

When the signal BLC1 of the data storage circuit 10 has the voltage Vdd+Vth, the bit line potential is Vdd if data “1” is stored in the PDC, and Vss if data “0” is stored in the PDC. Also, no data should be written in a memory cell of an unselected page (for which the bit line is unselected), which is connected to a selected word line. Therefore, Vdd is applied to the bit line connected to these cells, like cells in each of which data “1” is stored in the PDC.

When Vdd, Vpgm (20 V), and Vpass (10 V) are respectively applied to the select line SGS of a selected block, a selected word line, and an unselected word line in this state, write is performed if the bit line is at Vss because the channel of the cell is at Vss and the word line is at Vpgm.

On the other hand, if the bit line is at Vdd, the channel of the cell is not at Vss, but Vpgm, so about Vpgm/2 is obtained by coupling. Accordingly, no programming is performed.

In write of the first page, the memory cell data becomes data “0” or “1”. After write of the second page, the memory cell data becomes data “0”, “2”, “3”, or “4”.

### (Program Verify Read) (S14)

Program verify is performed at level “a” on the first page. The program verify operation is almost the same as the read operation.

First, the control signal & control voltage generator 7 applies the voltage Vfix (e.g., 1.6 V) to the well of a selected memory cell, the source line, an unselected bit line, and the select gate of an unselected block. A potential Vfix+“a′” (e.g., Vfix+“a′” is 1.2 V when “a′”=−0.4 V) (“′” indicates the verify voltage hereinafter and is slightly higher than the read voltage) slightly higher than the read potential Vfix+“a” is applied to a selected word line.

By applying the verify voltage Vfix+“a′” to the selected word line, a negative potential is apparently applied to the gate electrode of the memory cell. At the same time, Vread+Vfix is applied to an unselected word line of the selected block, Vsg (Vdd+Vth)+Vfix is applied to the select line SGD of the select gate S2 of the selected block, and Vfix is applied to the select line SGS of the select gate S1. In addition, Vfix is applied to the source line (SRC) and the well of the cell.

Then, the signals VPRE, BLPRE, and BLCLAMP of the data storage circuit 10 are respectively once set at Vdd (e.g., 2.5 V), Vsg (Vdd+Vth), and, e.g., (0.6 V+Vth)+Vfix, and the bit line is precharged to, e.g., 0.6 V+Vfix=2.2 V.

Subsequently, the select line SGS on the source side of the memory cell is set at Vsg (Vdd+Vth)+Vfix. Since the well and source are at Vfix, the memory cell is turned off if the threshold voltage of the memory cell is higher than verify level “a′” (e.g., a′=−0.4 V). Therefore, the bit line remains at High level (e.g., 2.2 V). Also, the memory cell is turned on if the threshold voltage of the memory cell is lower than verify level “a′”. Consequently, the bit line is discharged to the same potential as that of the source, i.e., Vfix (e.g., 1.6 V).

In this bit line discharge period, the signal DTG is once set at Vsg (Vdd+Vth), and data of the PDC is copied to the DDC.

After that, the signal BLPRE of the data storage circuit 10 is once set at Vsg (Vdd+Vth), and the node N3 of the TDC is precharged to Vdd. Then, the signal BOOST is changed from Low level to High level, and the node N3 of the TDC is set at αVdd (e.g., α=1.7, and αVdd=4.25 V). In this state, the signal BLCLAMP is set at, e.g., (0.45 V+Vth)+Vfix. The node N3 of the TDC changes to Low level (Vfix (e.g., 1.6 V)) if the bit line potential is lower than 0.45 V+Vfix, and remains at High level (αVdd (e.g., 4.25 V)) if the bit line potential is higher than 0.45 V.

Subsequently, after signal BLCLAMP=Vtr (e.g., 0.1 V+Vth) is set, the signal BOOST is changed from High level to Low level. If the TDC is at Low level, the potential of the node N3 decreases from Vfix (e.g., 1.6 V). However, the potential of the node N3 does not become lower than 0.1 V because the signal BLCLAMP is set at Vtr (e.g., 0.1 V+Vth).

On the other hand, if the TDC is at High level, the potential of the node N3 changes from αVdd (e.g., 4.25 V) to Vdd. In this state, the signal BLC1 is set at Vsg (Vdd+Vth), and the potential of the TDC is read out to the PDC. Then, the signals VREG and REG are respectively set at Vdd and Vsg (Vdd+Vth). If the DDC is at High level (non write), the TDC is forcedly set at High level. If the DDC is at Low level (non write), however, the value of the TDC remains unchanged.

In this state, the signal BLC1 is set at Vsg (Vdd+Vth), and the potential of the TDC is read out to the PDC. Accordingly, if the PDC is originally at Low level (write) and the threshold voltage of the memory cell is lower than verify level “a′”, the PDC is set at Low level (write) again. If the threshold voltage of the memory cell is higher than verify level “a′”, the PDC is set at High level. Accordingly, this memory cell is not written from the next programming loop. Also, if the PDC is originally at High level (non write), the PDC changes to High level, and the memory cell is not written from the next programming loop.

The above-mentioned operation is repeated (S15-S13) until the PDCs of all the data storage circuits 10 change to High level (“1”).

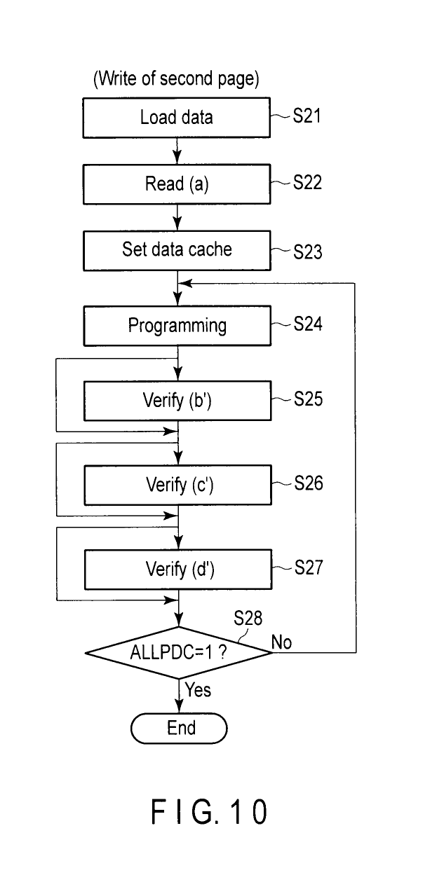

On the other hand, the write operation of the second page shown in FIG. 10 is almost the same as that of the first page. However, after externally supplied write data is set in the PDC, a read operation is performed at level “a” in order to check the data written in the first page (S21 and S22). After that, data is set in the PDC by using the readout data and externally supplied write data (S23). That is, as shown in FIG. 8B, data “0” is set in the PDC when the data of the first page is “1” and that of the second page is “0” and when the data of the first page is “0” and that of the second page is “1”, and data “1” is set in the PDC in other cases.

In this state, the programming operation described above is executed (S24).

After that, program verify is executed (S25, S26, and S27). Program verify of the second page is executed in almost the same manner as that performed at verify level “a′” by sequentially setting verify levels “b′”, “C′”, and “d′”.

When the program verify operation is performed at verify level “b′” when writing the second page, cells to be written to levels “c” and “d” are not written by program verify at level “b′”. Therefore, when, e.g., performing write at verify levels “c′” and “d′”, the node N2a of the data storage circuit 10 is set at High level. When performing write at verify level “b′”, the node N2a is set at High level, and the signal REG is set at Vsg. When writing no data, the signal BLC2 is set at Vtr (0.1 V+Vth) before the operation of forcedly changing the TDC to High level. When writing data at verify levels “c′” and “d′”, the TDC is forcedly changed to Low level, so as not to complete write by program verify at verify level “b′”.

Also, when the above-mentioned operation is performed as program verify at verify level “c′” when writing the second page, cells to be written to level “d” are not written by program verify at verify level “c′”. Therefore, when writing data to level “c”, for example, the node N1a of the data storage circuit 10 is set at Low level. In other cases, the node N1a of the data storage circuit 10 is set at Low level, and the signal REG is set at Vsg. Also, when writing no data, the signal BLC1 is set at Vtr (0.1 V+Vth) before the operation of forcedly changing the TDC to High level. Furthermore, when writing data at verify level “d′”, the TDC is forcedly set at Low level, so as not to complete write by program verify at verify level “d′”.

When the PDC is at Low level, the write operation is performed again, and the programming operation and verify operation are repeated until the PDC data of all the data storage circuits 10 change to High level (S28-S24).

### (Erase Operation)

An erase operation is performed for each block indicated by, e.g., the broken lines in FIG. 2. After erase, the threshold voltage of the memory cell becomes data “0” as shown in FIG. 8C.

After the erase operation, programming and program verify read are executed by selecting all word lines in the block, and a write operation is performed to level “z” as shown in FIG. 8C. In the programming operation and program verify read operation, all word lines are selected, and the potential of a selected word line is set at level “z”+Vfix (e.g., 0 V) in verify. The rest of the operation is exactly the same as normal programming and program verify read.

### First Embodiment

In this embodiment as described previously, adjacent bit lines are formed in different interconnection layers in order to reduce the capacitance of the bit lines.

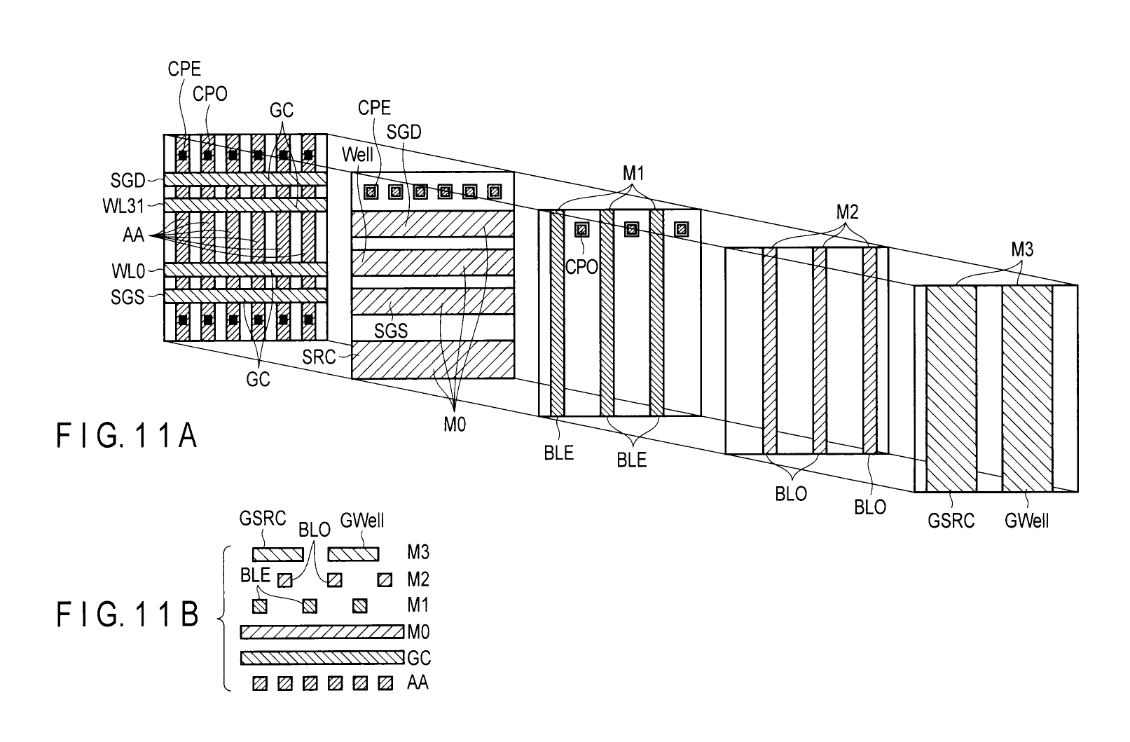

FIGS. 11A and 11B schematically show the arrangements of a memory cell and select gate of a NAND flash memory according to this embodiment. For descriptive convenience, interlayer dielectric films and the like are omitted.

As shown in FIGS. 11A and 11B, gate electrodes GC of memory cell transistors forming word lines are formed above active areas AA as the source and drain regions formed in a semiconductor substrate (not shown). Select lines SGS and SGD of select gates, a source line SRC, and an interconnection Well for supplying a potential to the well are formed above the gate electrodes GC by first metal interconnection layers M0. However, when the time constants of the select lines SGS and SGD of the select gates are small, for example, the interconnections M0 as shunts are unnecessary, and the interconnection well may also be omitted.

Above the first metal interconnection layers M0, even-numbered bit lines BLE are formed by second metal interconnection layers M1, and odd-numbered bit lines BLO are formed by third metal interconnection layers M2. In the following description, the bit lines BLE represent BL0, BL2, . . . , BL(i−2), BLi, . . . , BL(k−2) shown in FIG. 2, and BL0e, BL0o, BL2e, BL2o, . . . , BL(i−2)e, BL(i−2)o, BLie, BLio, . . . , BL(k−2)e, and BL(k−2)o shown in FIG. 3. Also, the bit lines BLO represent BL1, BL3, . . . , BL(i−1), BL(i+1), . . . , BL(k−1) shown in FIG. 2, and BL1e, BL1o, BL3e, BL3o, . . . , BL(i−1)e, BL(i−1)o, BL(i+1)e, BL(i+1)o, . . . , BL(k−1)e, and BL(k−1)o. However, when the resistance of the interconnection Well for supplying a potential to the source line SRC and well is low, for example, the interconnections M2 as shunts are unnecessary and can also be omitted. That is, the even-numbered bit lines BLE are arranged to face every other active area AA, and the odd-numbered bit lines BLO are arranged above the spacings between the even-numbered bit lines BLE. That is, the odd-numbered bit lines BLO are also arranged to face every other active area AA.

Furthermore, a global source line GSRC and global interconnection GWell are formed above the third metal interconnection layers M2 by fourth metal interconnection layers M3. The global source line GSRC and the global interconnection GWell are respectively connected to the source line SRC and the interconnection Well for supplying a potential to the well.

The bit lines BLE and BLO are arranged above the active areas AA. Contact plugs CPE and CPO are arranged on the active areas AA outside the select line SGS of the select gates (the side opposite to the side on which word lines WL0 to WL31 are arranged). The bit lines BLE are electrically connected to the active areas AA by the contact plugs CPE. The bit lines BLO are electrically connected to the active areas AA by the contact plugs CPO. That is, the contact plugs CPO extend between the bit lines BLE.

The distance between the bit lines BLE is equal to a distance obtained by adding the width of the active area AA and the double of the distance between the active areas AA. Likewise, the distance between the bit lines BLO is equal to a distance obtained by adding the width of the active area AA and the double of the distance between the active areas AA.

As described above, the even-numbered bit lines BLE are formed by the second metal interconnection layers M1, and the odd-numbered bit lines BLO are formed by the third metal interconnection layers M2. When the widths of the bit lines BLE and BLO are the same, for example, the distance between adjacent bit lines BLE and the distance between adjacent bit lines BLO can be made about three times the distance when the bit lines BLE and BLO are arranged adjacent to each other in the same interconnection layer. This makes it possible to reduce the capacitance between the bit lines BLE to about ⅓, and reduce the CR time constant of the bit line to about ⅓.

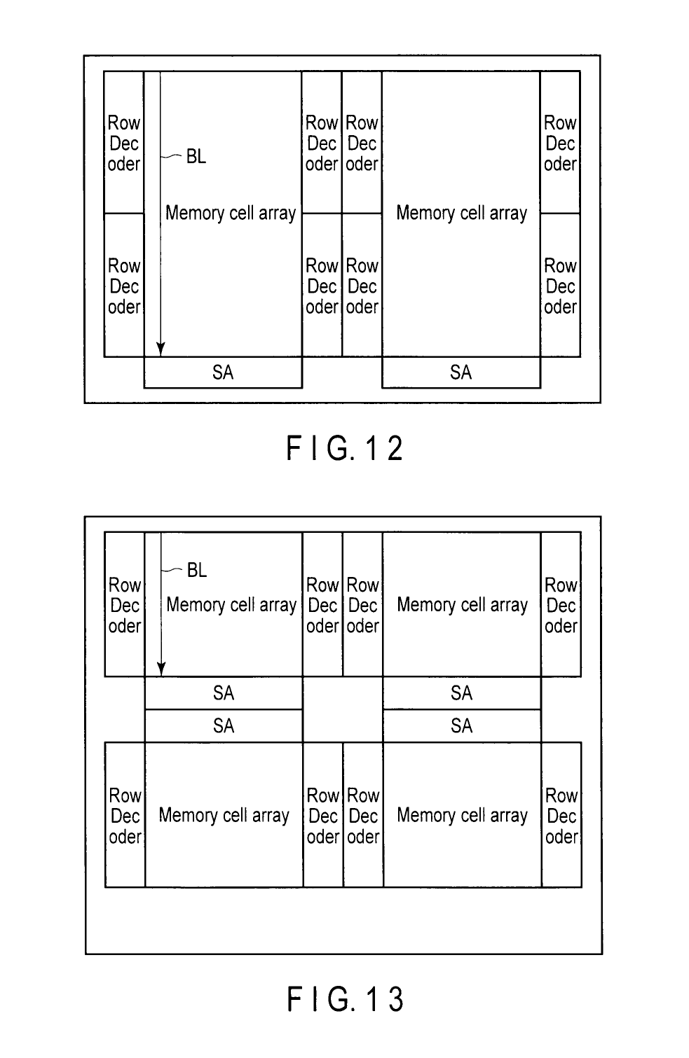

FIG. 12 shows the floor plan of the semiconductor memory device according to this embodiment. FIG. 13 shows the floor plan of a general semiconductor memory device. Referring to FIG. 13, odd-numbered bit lines and even-numbered bit lines are formed in the same interconnection layer. Assume that the storage capacities of the semiconductor memory devices shown in FIGS. 12 and 13 are almost equal.

That is, when the CR time constant is large, the length of the bit lines BL is decreased in order to increase the operation speed. When the length of the bit lines BL is decreased, the distance the bit lines BL can run on the memory cell array shortens. Consequently, the memory cell array is divided in the direction in which the bit lines BL run. That is, the number of bit lines BL in the semiconductor device increases. In the example shown in FIG. 13, for example, each bit line BL is divided into two parts in the direction in which the bit lines BL run, when compared to the example shown in FIG. 12. That is, the number of bit lines BL doubles. Since the number of sense amplifiers SA is proportional to the number of bit lines BL, the number of sense amplifiers SA in the semiconductor device increases.

The above-mentioned arrangement of this embodiment can reduce the bit line capacitance and CR time constant. Accordingly, the length of the bit lines BL can be made about twice that in the example shown in FIG. 13. This makes it possible to decrease the number of sense amplifiers SA (data storage circuits) when compared to the example shown in FIG. 13. Therefore, the semiconductor memory device shown in FIG. 13 is formed by four planes including four memory cell arrays, whereas the semiconductor memory device according to this embodiment can be formed by two planes including two memory cell arrays. As a consequence, the chip size can be made smaller than that shown in FIG. 13, so the manufacturing cost can be reduced. Especially in a multi-chip package (MCP) in which a plurality of chips are accommodated in one package, pads are desirably arranged on one side of the chip. When pads PA are arranged along, e.g., the lower sides in FIGS. 12 and 13 of the chips, a power supply line is extended to the central portion of the chip in the arrangement shown in FIG. 13, but that is unnecessary in the arrangement shown in FIG. 12. This makes it possible to suppress the increase in length of the power supply line.

FIG. 14 shows the relationship between the bit lines BLO and BLE and the contacts shown in FIGS. 11A and 11B. The first metal interconnection layers M0 are connected to the active areas AA via the contact plugs CP. The even-numbered bit lines BLE are connected to the first metal interconnection layers M0 via first vias V1. The odd-numbered bit lines BLO are connected to the first metal interconnection layers M0 via second vias V2, the second metal interconnection layers M1, and the first vias V1.

The contact plugs CP are made of, e.g., polysilicon. The first vias V1 are formed by so-called dual damascene by using, e.g., the second metal interconnection layers M1. The second vias V2 are formed by dual damascene together with, e.g., the odd-numbered bit lines BLO by using, e.g., the third metal interconnection layers M2.

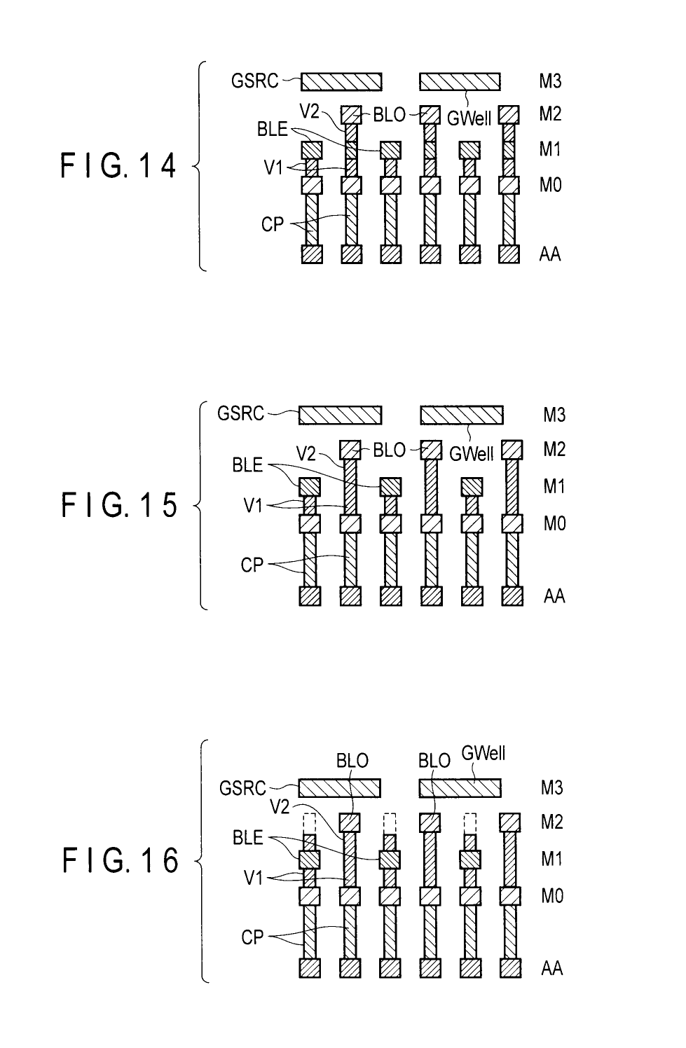

FIG. 15 shows the first modification of FIG. 14. FIG. 16 shows the second modification of FIG. 14. The same reference symbols as in FIG. 14 denote the same parts in FIGS. 15 and 16, and only different portions will be explained below.

In the first modification shown in FIG. 15, the odd-numbered bit lines BLO are connected to the first metal interconnection layers M0 by the second vias V2. The second vias V2 are formed by dual damascene together with, e.g., the odd-numbered bit lines BLO and first vias V1 by using, e.g., the third metal interconnection layers M2.

The first modification can also form the planar structure shown in FIGS. 11A and 11B.

In the second modification shown in FIG. 16, the even-numbered bit lines BLE are formed by the second metal interconnection layers M1. The second vias V2 are formed by, e.g., the third metal interconnection layers M2 (the same material as that of the third metal interconnection layers M2), and connect the odd-numbered bit lines BLO and first metal interconnection layers M0. The first vias V1 are formed to extend through the even-numbered bit lines BLE, and connect the even-numbered bit lines BLE and first metal interconnection layers M0.

The second modification can also form the planar structure shown in FIGS. 11A and 11B.

Note that in FIG. 16, the vias on the even-numbered bit lines BLE can also be formed by the third metal interconnection layers M2. In this case, these vias can also be formed to the same level as that of the third metal interconnection layers M2 as indicated by the broken lines in FIG. 16.

In the above-mentioned first embodiment, the even-numbered bit lines BLE and odd-numbered bit lines BLO are formed in different interconnection layers. Therefore, the spacing between bit lines formed in the same interconnection layer can be made larger than that when the even-numbered bit lines BLE and odd-numbered bit lines BLO are formed in the same interconnection layer. This makes it possible to reduce the capacitance between the bit lines, and reduce the CR time constant of the bit lines. Since the bit line length can be increased accordingly, the number of memory cells connected to one bit line can be increased. Therefore, it is possible to decrease the number of sense amplifiers and reduce the chip area.

In this embodiment, the first or second vias V1 or V2 are connected to the contact plugs CP via the first metal interconnection layers M0. However, the first or second vias V1 or V2 can also be connected directly to the contact plugs CP without the first metal interconnection layers M0.

### Second Embodiment

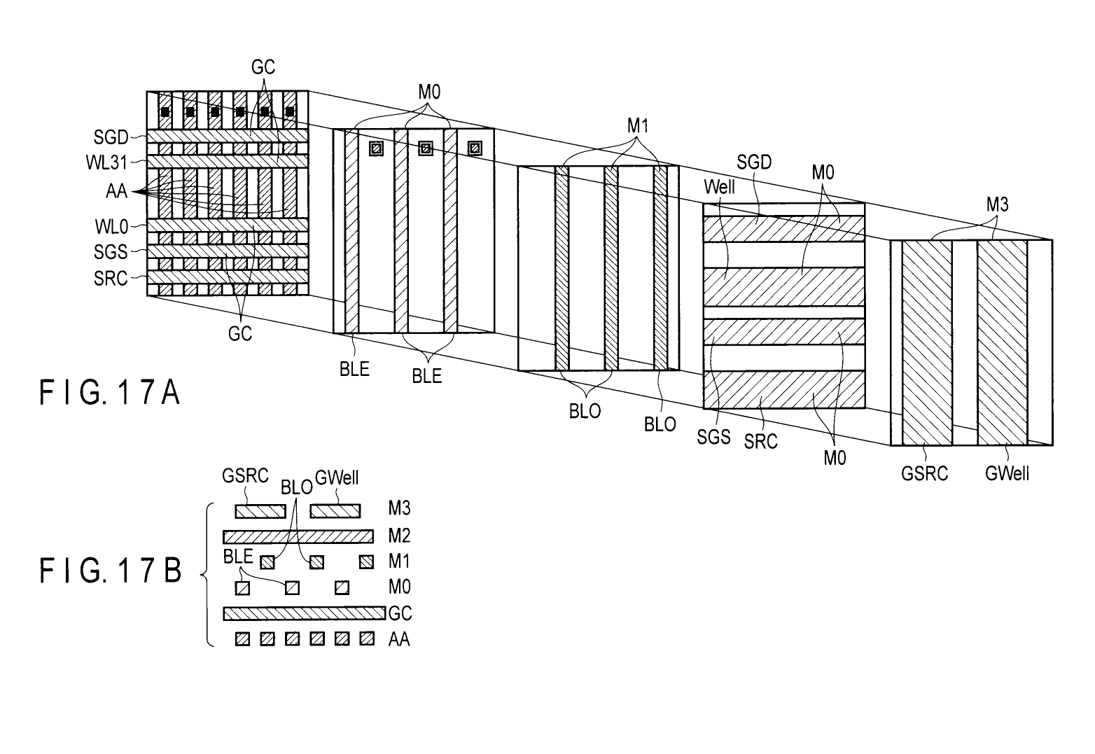

FIGS. 17A and 17B illustrate the second embodiment. In the second embodiment, the same reference symbols as in the first embodiment denote the same parts.

In the first embodiment shown in FIGS. 11A and 11B, the even-numbered bit lines BLE are formed in the second metal interconnection layer M1, and the odd-numbered bit lines BLO are formed in the third metal interconnection layer M2.

By contrast, in the second embodiment shown in FIGS. 17A and 17B, even-numbered bit lines BLE are formed in a first metal interconnection layer M0, and odd-numbered bit lines BLO are formed in a second metal interconnection layer M1. A source line SRC, select lines SGS and SGD, and an interconnection Well for supplying power to the well are formed in a third metal interconnection layer M2.

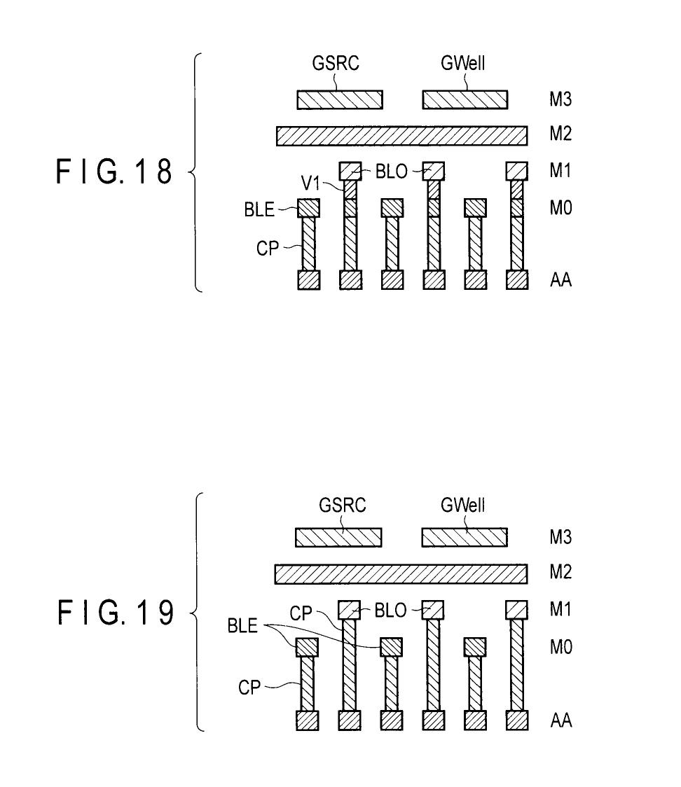

FIG. 18 shows the relationship between the bit lines BLO and BLE and contacts in the second embodiment. The even-numbered bit lines BLE are connected to active areas AA via contact plugs CP. The odd-numbered bit lines BLO are connected to the active areas AA via the contact plugs CP and first vias V1. The contact plugs CP are made of, e.g., polysilicon. The first vias V1 are formed by so-called dual damascene by using, e.g., the second metal interconnection layer M1. The contact plugs CP are formed by so-called dual damascene by using, e.g., the first metal interconnection layer M0. The first vias V1 can also be formed by dual damascene by using, e.g., the second metal interconnection layer M1.

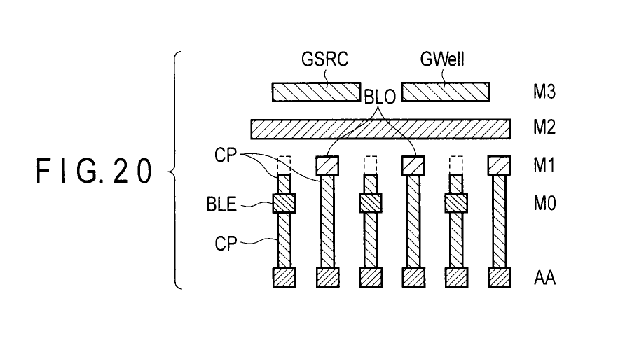

FIG. 19 shows the first modification of the arrangement shown in FIG. 18. FIG. 20 shows the second modification of the arrangement shown in FIG. 18. The same reference symbols as in FIG. 18 denote the same parts in FIGS. 19 and 20, and only different portions will be explained.

In the first modification shown in FIG. 19, the odd-numbered bit lines BLO are also connected to the active areas AA via the contact plugs CP, like the even-numbered bit lines BLE. The first modification can also implement an arrangement similar to that shown in FIG. 18.

In the second modification shown in FIG. 20, the contact plugs CP are formed to extend through the even-numbered bit lines BLE. Therefore, the contact plugs CP to be connected to the odd-numbered bit lines BLO and even-numbered bit lines BLE can be formed at the same time. This makes it possible to reduce manufacturing steps.

Note that in FIG. 20, the vias on the even-numbered bit lines BLE may also be formed by the second metal interconnection layer M1. In this case, the vias can be formed to the same level as that of the second metal interconnection layer M1 as indicated by the broken lines in FIG. 16.

The above-mentioned second embodiment can also achieve the same effects as those of the first embodiment.

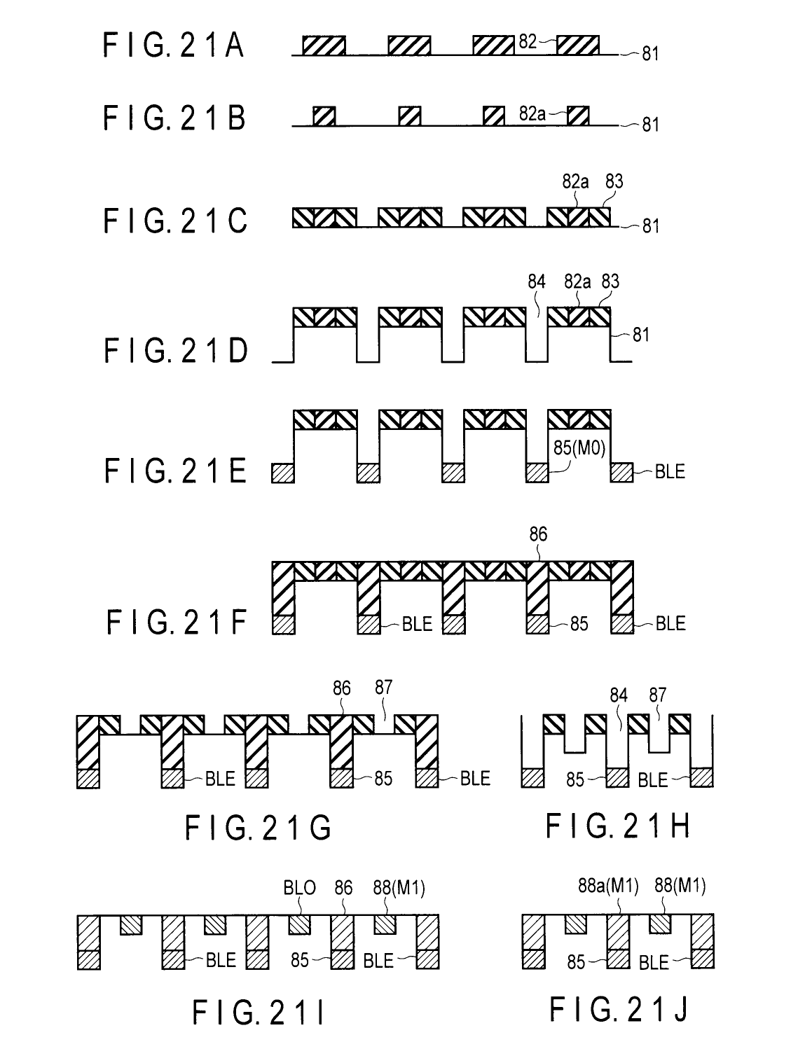

FIGS. 21A, 21B, 21C, 21D, 21E, 21F, 21G, 21H, 21I, and 21J show examples of manufacturing steps when forming even-numbered bit lines BLE and odd-numbered bit lines BLO in different metal interconnection layers as described above.

As shown in FIG. 21A, resist films 82, for example, as patterned core materials are formed on an interlayer dielectric film 81. The width of the resist film 82 is formed to have a pitch about twice the width (to be referred to as a target width hereinafter) of a bit line to be formed. The width of the resist film 82 and the space between the resist films 82 are preferably equal. Note that hard masks may also be formed by transferring the resist films 82 onto a mask material or the like.

As shown in FIG. 21B, resist films 82a each having the target width (almost the same width as that of an active area AA) are formed by slimming the resist films 82.

As shown in FIG. 21C, sidewalls 83 are formed on the two sides of each slimmed resist film 82a. The width of the sidewall is set to be equal to the target width. That is, the total width of the resist film 82a and the sidewalls 83 on the two sides of the resist film 82a is about three times the target width. Also, the distance between the sidewalls 83 is almost equal to the target width.

As shown in FIG. 21D, the interlayer dielectric film 81 is etched by using the resist films 82a and sidewalls 83 as masks, thereby forming trenches 84. The depth of the trench 84 is set to be, e.g., about three times the target width.

As shown in FIG. 21E, even-numbered bit lines BLE are formed by forming first metal interconnection layers M0 in the trenches 84. In this step, it is possible to simultaneously bury a conductor for forming the first metal interconnection layers M0 in holes of contact plugs CP connected to the bottoms of the trenches 84. The contact plugs CP and first metal interconnection layers M0 are formed by dual damascene, so a manufacturing step can be omitted. In this case, after the conductor is deposited on the entire surface, the conductor remaining on the upper surfaces of the resist films 82a and sidewalls 83 is removed by anisotropic etching or the like, so that the first metal interconnection layers M0 only remain on the bottoms of the trenches 84 and in the holes of the contact plugs CP.

As shown in FIG. 21F, insulting films 86 are buried in the trenches 84. The insulating films 86 are formed by a material having an etching rate higher than those of the interlayer dielectric film 81 and insulating films 83. The insulating films 86 can protect the upper portions of the first metal interconnection layers M0 from being oxidized, and further decrease the resistance of bit lines BL. In this step, it is favorable to remove the insulating films 86 formed on the resist films 82a as shown in FIG. 21F. Also, the insulating films 86 are not buried in, for example, those positions of the trenches 84, in which vias are to be formed. Note that vias may also be formed by once burying the insulating films 86 and then removing the buried materials from the via formation positions.

As shown in FIGS. 21G and 21H, the resist films 82a are removed, and the interlayer dielectric film 81 is etched by using the insulating films 83 as masks, thereby forming trenches 87 for forming bit lines. In this step, as shown in FIG. 21H, the insulating films 86 are also etched in the via portions like the insulating dielectric film 81. In this step, the bottom of each trench 87 is made shallower than the upper surface of the first metal interconnection layer M0 by controlling the etching rates of the insulating films 86 and interlayer dielectric film 81. As a consequence, a manufacturing step can be omitted.

As shown in FIGS. 21I and 21J, odd-numbered bit lines BLO are formed by removing the insulating films 83, and burying second metal interconnection layers M1. In this step, as shown in FIG. 21J, vias 88a are formed by the second metal interconnection layers M1. A semiconductor memory device can be manufactured by the well-known manufacturing method.

Note that it is also possible to simultaneously form the odd-numbered bit lines BLO and vias by using a dual damascene process, instead of a so-called single damascene process.

In the above-mentioned manufacturing method, the even-numbered and odd-numbered bit lines are respectively formed in the first and second metal interconnection layers M0 and M1. However, this manufacturing method is also applicable when respectively forming the even-numbered and odd-numbered bit lines in the second and third metal interconnection layers M1 and M2.

A plurality of metal interconnection layers are normally formed by forming interlayer dielectric films between them so that the metal interconnection layers do not contact each other. In this embodiment, however, the capacitance between adjacent bit lines arranged in the same layer can be reduced. This obviates an interlayer dielectric film formed between bit lines in different layers.

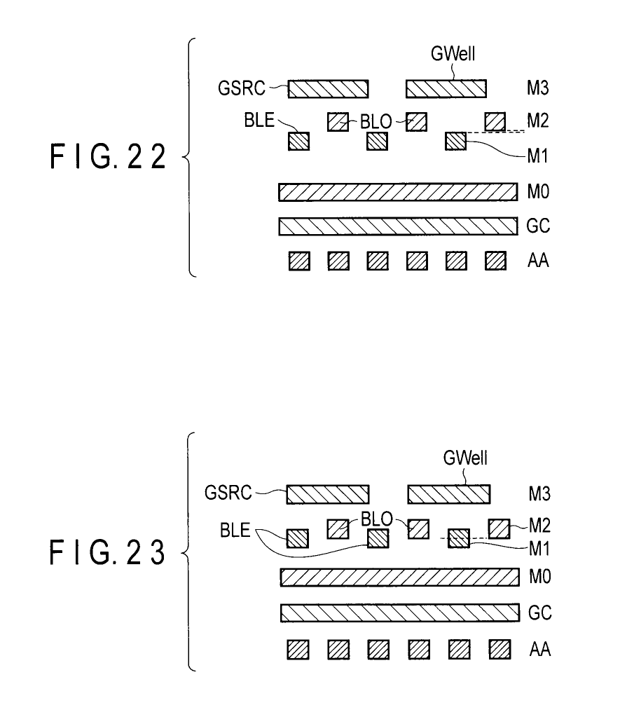

For example, in an arrangement shown in FIG. 22 as a modification of FIGS. 14, 15, and 16, interlayer dielectric film is not formed between the bit lines BLE in the first layer (the second metal interconnection layer M1) and the bit lines BLO in the second layer (the third metal interconnection layer M2).

More specifically, in the arrangement shown in FIG. 22, between the bit lines BLE in the first layer (the second metal interconnection layer M1) and the bit lines BLO in the second layer (the third metal interconnection layer M2), an interlayer dielectric film thinner than those shown in FIGS. 14, 15, and 16 and FIGS. 18, 19, and 20 is formed, or interlayer dielectric film is not formed.

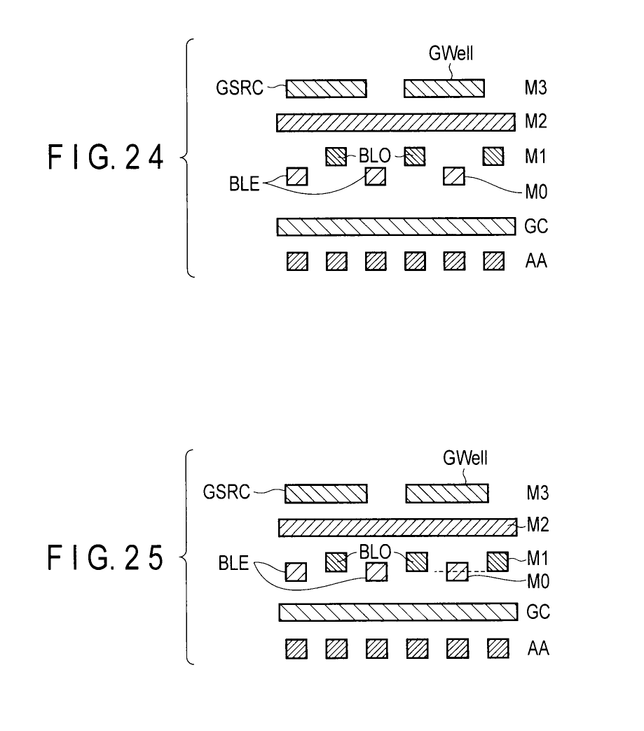

Also, in an arrangement shown in FIG. 24 as a modification of FIGS. 18, 19, and 20, interlayer dielectric film is not formed between the bit lines BLE in the first layer (the first metal interconnection layer M0) and the bit lines BLO in the second layer (the second metal interconnection layer M1).

That is, a thin interlayer dielectric film is formed or no interlayer dielectric film is formed between the bit lines BLE in the first layer (the first metal interconnection layer M0) and the bit lines BLO in the second layer (the second metal interconnection layer M1) in the arrangement shown in FIG. 24 as well. When omitting an interlayer dielectric film, the upper surfaces of the bit lines BL in the first layer may be higher than the lower surfaces of the bit lines BLO in the second layer.

In the arrangements shown in FIGS. 22 and 24, therefore, the thicknesses of the whole semiconductor memory devices can be made very small.

Furthermore, it is also possible not to form interlayer dielectric film between the bit lines BLE in the first layer (the second metal interconnection layer M1) and the bit lines BLO in the second layer (the third metal interconnection layer M2) as in a modification shown in FIG. 23, and not to form interlayer dielectric film between the bit lines BLE in the first layer (the first metal interconnection layer M0) and the bit lines BLO in the second layer (the second metal interconnection layer M1) as in a modification shown in FIG. 25. That is, the upper surfaces of the bit lines BLE in the first layer are higher than the lower surfaces of the bit lines BLO in the second layer.

In the arrangements shown in FIGS. 23 and 25, the bit lines BLO in the second layer are partially arranged between the bit lines BLE in the first layer. Therefore, the thicknesses of the whole semiconductor memory devices can be made farther smaller than those shown in FIGS. 22 and 24. This makes it possible to decrease the aspect ratio of the contact hole for connecting the interconnections. Accordingly, the processing accuracy can be increased.

Note that in the modifications shown in FIGS. 22, 23, 24, and 25, peripheral circuits can be formed by using only one of the metal interconnection layers of the bit lines BLE in the first layer and the bit lines BLO in the second layer, or by using a thick metal interconnection layer by combining the metal interconnection layers of the bit lines BLE in the first layer and the bit lines BLO in the second layer. When using a thick metal interconnection layer, the resistance of the metal interconnection can be decreased.

In the above embodiments, the bit lines BL in the lower layer are BLE, and the bit lines BL in the upper layer are BLO. However, the bit lines BL in the lower layer may be formed as BLO, and the bit lines BL in the upper layer may be formed as BLE.

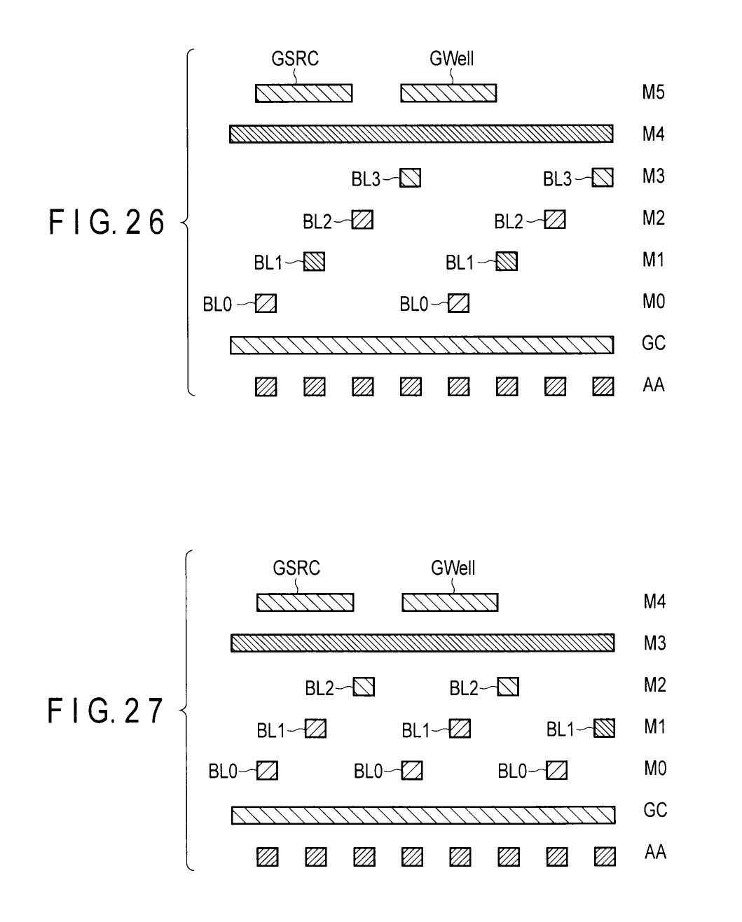

FIGS. 26, 27, and 28 show other modifications.

In the examples shown in FIGS. 26 and 27, the distance between bit lines BLO, the distance between bit lines BL1, the distance between bit lines BL2, and the distance between bit lines BL3 are equal to a distance obtained by adding the width of the active area AA and the quadruple or triple of the distance between the active areas AA. In these arrangements, the capacitance between the bit lines can further be reduced.

The example shown in FIG. 26 can be formed by further repeating the manufacturing steps shown in FIGS. 21A, 21B, 21C, 21D, 21E, 21F, 21G, 21H, 21I, and 21J.

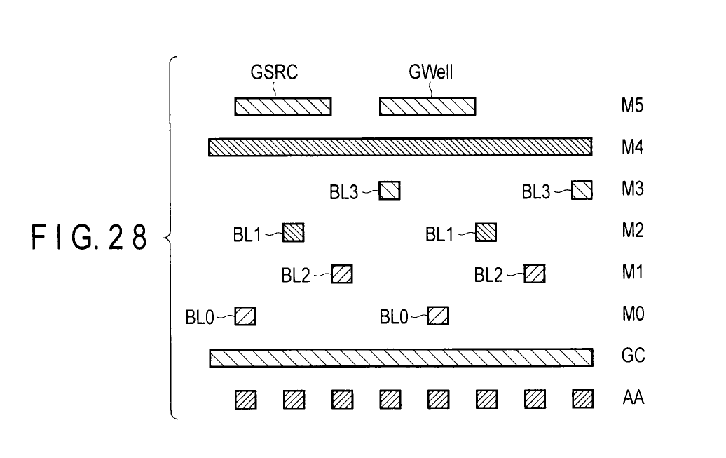

FIG. 28 shows a modification of FIG. 26. Referring to FIG. 28, the oblique distance between the bit lines BL0 and BL1 and the oblique distance between the bit lines BL2 and BL3, except for the bit lines BL1 and BL2, are longer than those in the example shown in FIG. 26. It is also possible to increase the distances between all the bit lines by making an interlayer dielectric film between the bit lines BL1 and BL2 thicker than those between other bit lines. This arrangement can further reduce the capacitance between the bit lines.

As shown in FIG. 3, bit lines BL(i−2)e and BL(i−2)o arranged in the same layer are connected to one data storage circuit 10, and bit lines BL(i−1)e and BL(i−1)o arranged in the same layer are connected to one data storage circuit 10.

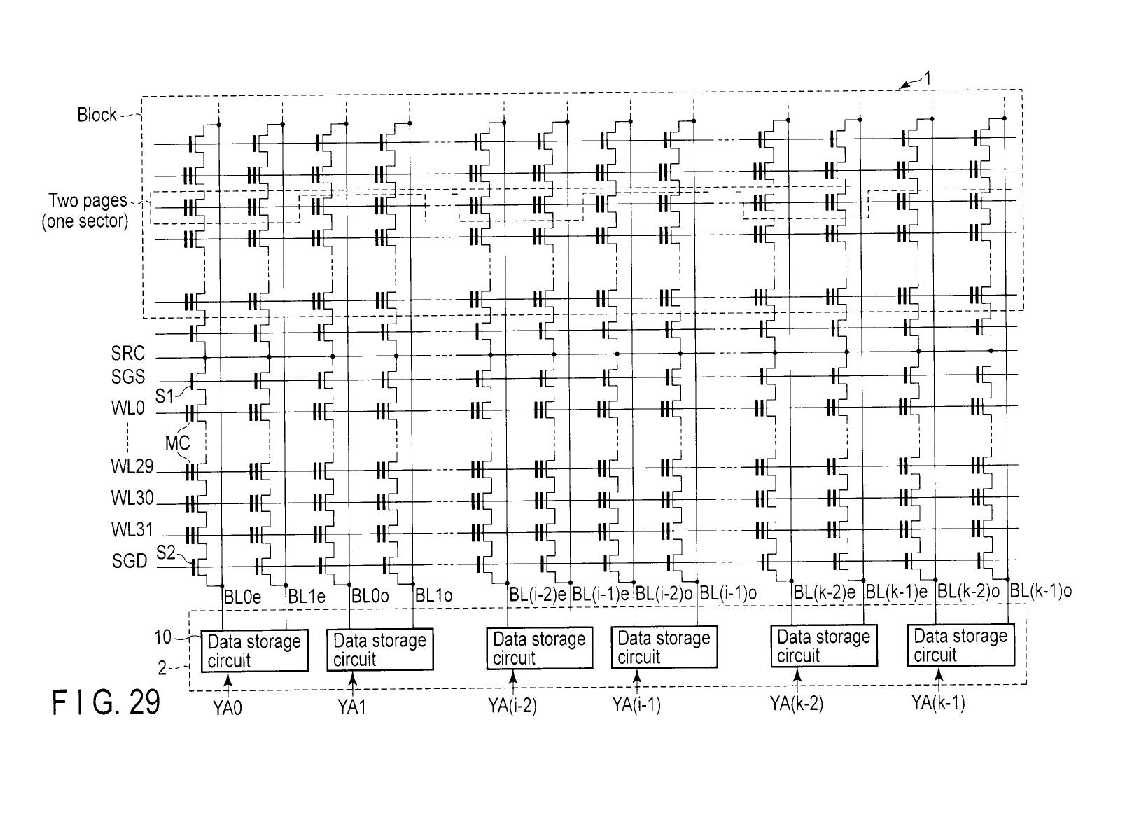

However, as shown in FIG. 29, it is possible to constitute bit lines. That is, for example, bit lines BL(i−2)e and BL(i−1)e arranged in different layers are connected to the data storage circuit 10, and bit lines BL(i−2)o and BL(i−1)o arranged in different layers are connected to the data storage circuit 10. In this case, when bit lines BL(i−2)e and BL(i−1)o are selected, bit lines BL(i−1)e and BL(i−2)o are unselected, and when bit lines BL(i−1)e and BL(i−2)o are selected, bit lines BL(i−2)e and BL(i−1)o are unselected.

Moreover, the configuration shown in FIG. 29 is that the bit line BL(i−1)e arranged in the different layer from the bit line BL(i−2)e is connected to one data storage circuit 10, and the bit line BL(i−1)o arranged in different layer from the bit line BL(1−2)o is connected to one data storage circuit 10. However, the configuration shown in FIG. 29 can be modified as follows. That is, bit lines BL0e, BL0o, BL2e, BL2o, . . . BL(i−2)e, and BL(i−2)o may be selected as one page, and bit lines BL1e, BL1o, BL3e, BL3o, . . . BL(i−1)e, and BL(i−1)o . . . may be selected as another one page. In this configuration, since the adjacent bit lines on the same layer are selected simultaneously, these bit lines have no relation by which one of bit lines is selected and the other one of bit lines is unselected. However, these bit lines arranged in different layers are shielded mutually.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a plurality of memory cells arranged in a matrix;
a plurality of word lines configured to select the plurality of memory cells; and
a plurality of bit lines configured to select the plurality of memory cells,
wherein first bit lines and second bit lines included in the plurality of bit lines are arranged in different layers.

2. The device according to claim 1, wherein the first bit lines are arranged in a first interconnection layer, and the second bit lines are arranged in a second interconnection layer.

3. The device according to claim 2, further comprising:
a first data storage circuit connected to a pair of first bit lines arranged in the first interconnection layer; and
a second data storage circuit connected to a pair of second bit lines arranged in the second interconnection layer.

4. The device according to claim 2, wherein upper surfaces of the first bit lines arranged in the first interconnection layer are substantially leveled with lower surfaces of the second bit lines arranged in the second interconnection layer.

5. The device according to claim 2, wherein upper surfaces of the first bit lines arranged in the first interconnection layer are higher than lower surfaces of the second bit lines arranged in the second interconnection layer.

6. A semiconductor memory device comprising:
a plurality of memory cells arranged in a matrix;
a plurality of word lines configured to select the plurality of memory cells; and
a plurality of bit lines configured to select the plurality of memory cells,
wherein among a first bit line, a second bit line, a third bit line, and a fourth bit line adjacent to each other in the plurality of bit lines, the first bit line and the third bit line are formed in a first interconnection layer, and the second bit line and the fourth bit line are formed in a second interconnection layer.

7. The device according to claim 6, wherein the first bit line and the second bit line are simultaneously set in a selected state, and the third bit line and the fourth bit line are simultaneously set in an unselected state.

8. The device according to claim 6, further comprising:
a first data storage circuit connected to the first bit line and the third bit line; and
a second data storage circuit connected to the second bit line and the fourth bit line.

9. The device according to claim 6, wherein upper surfaces of the first bit line and the third bit line arranged in the first interconnection layer are substantially leveled with lower surfaces of the second bit line and the fourth bit line arranged in the second interconnection layer.

10. The device according to claim 6, wherein upper surfaces of the first bit line and the third bit line arranged in the first interconnection layer are higher than lower surfaces of the second bit line and the fourth bit line arranged in the second interconnection layer.

11. A semiconductor memory device manufacturing method comprising:
forming, on a first insulating film, a first film having a width larger than a width of a bit line to be formed;
forming a second film by slimming the first film into the width of the bit line to be formed;
forming second insulating films on sidewalls of the second film;
forming a first trench having a first depth in the first insulating film by using the second film and the second insulating films as masks;
forming a first bit line in the first trench by using a first conductive material;
filling the first trench with a third insulating film;
removing the second film;
forming a second trench shallower than the first depth in the first insulating film by using the second insulating films as masks; and
forming a second bit line in the second trench by using a second conductive material.

12. The method according to claim 11, wherein
when filling the first trench with the third insulating film, the third insulating film is buried in the first trench except for a via formation region, and
when forming the second bit line, a via is formed in the region by using the second conductive material.
